(19) United States
(12) Patent Application Publication
(10) Pub. No.: US 2011/0183269 A1
(43) Pub. Date: Jul. 28, 2011

(54) Methods Of Forming Patterns, And Methods For Trimming Photoresist Features

(76) Inventor: Hongbin Zhu, Boise, ID (US)

(21) Appl. No.: 12/693,321

(22) Filed: Jan. 25, 2010

(51) Int. Cl. G03F 7/20; G03F 7/00

(52) U.S. Cl. 430/319; 430/401; 430/322; 430/323

(57) ABSTRACT

Some embodiments include methods of forming patterns. Photoresist features may be formed over a base, with the individual photoresist features having heights and widths. The photoresist features may be exposed to a combination of chloroform, oxidant and additional carbon-containing material besides chloroform to reduce the widths of the photoresist features while substantially maintaining the heights of the photoresist features. The photoresist features may then be used as a mask to pattern the underlying base, and/or spacers may be formed to be aligned to sidewalls of the photoresist features, and the spacers may be used as the mask to pattern the underlying base.

### TECHNICAL FIELD

Methods of forming patterns, and methods for trimming photoresist features.

### BACKGROUND

Integrated circuits may be formed on a semiconductor substrate, such as a silicon wafer or other semiconducting material. In general, layers of various materials which are either semiconducting, conducting or insulating are patterned to form components of the integrated circuits. By way of example, the various materials may be doped, ion implanted, deposited, etched, grown, etc., using various processes.

Photolithography is commonly utilized during integrated circuit fabrication. Photolithography comprises patterning of photoresist by exposing the photoresist to a pattern of actinic energy, and subsequently developing the photoresist. The patterned photoresist may then be used as a mask, and a pattern may be transferred from the photolithographically-patterned photoresist to underlying materials.

A continuing goal in semiconductor processing is to reduce the size of individual electronic components, and to thereby enable smaller and denser integrated circuitry. Accordingly, it is desired to form ever-smaller masking features, which in turn may be utilized to form ever-smaller electronic components. One method for reducing the size of photoresist features is to subject such features to conditions suitable for trimming the features. Generally, it is desired to reduce a size of the photoresist features along a lateral dimension (i.e., width) while substantially maintaining a vertical dimension (i.e., height) of the photoresist features. In other words, it is desired to reduce the footprint of the photoresist features, while maintaining the height of the photoresist features. One of the reasons that it may be desired to maintain the height of the photoresist features is in order to have plenty of masking material available in the event that there may be some loss of the masking material during subsequent processing (for instance, etching). Another reason that it may be desired to maintain heights of photoresist features is because the photoresist features may be utilized to pattern sidewall spacers in subsequent processing, and the heights of the sidewall spacers may be limited by the heights of the photoresist features.

Other continuing goals in semiconductor processing are to achieve high throughput, and to reduce costs.

Present methods for trimming photoresist may undesirably reduce heights of photoresist features while laterally trimming the features, and/or may have high material costs, and/or may fail to achieve desired throughput. Accordingly, it would be desired to develop new methods for trimming photoresist.

### BRIEF DESCRIPTION OF THE DRAWINGS

FIGS. 1-9 are diagrammatic cross-sectional views of a portion of a semiconductor construction at various process stages of an example embodiment method.

FIG. 10 is a diagrammatic cross-sectional view of a portion of an example base that may be patterned in some embodiments.

### DETAILED DESCRIPTION OF THE ILLUSTRATED EMBODIMENTS

Some embodiments include methods which may be utilized to trim photoresist features in a manner which reduces widths of the features without substantially reducing heights of the features. Such methods utilize chloroform (CHCl₃) in the etchant together with an appropriate oxidant (for instance, O₂), and may additionally utilize another carbon containing material besides chloroform (example carbon-containing materials that may be utilized are CO, CHF₃, CH₄, CO₂, CF₄, and CH₂F₂). In some embodiments, the trimmed photoresist features may be utilized as a mask during subsequent processing; such as, for example, as a mask during implant of dopant into an underlying material and/or as a mask during an etch into an underlying material. In some embodiments, the trimmed photoresist features may be utilized as a template for patterning spacers in accordance with, for example, pitch-multiplying methodologies.

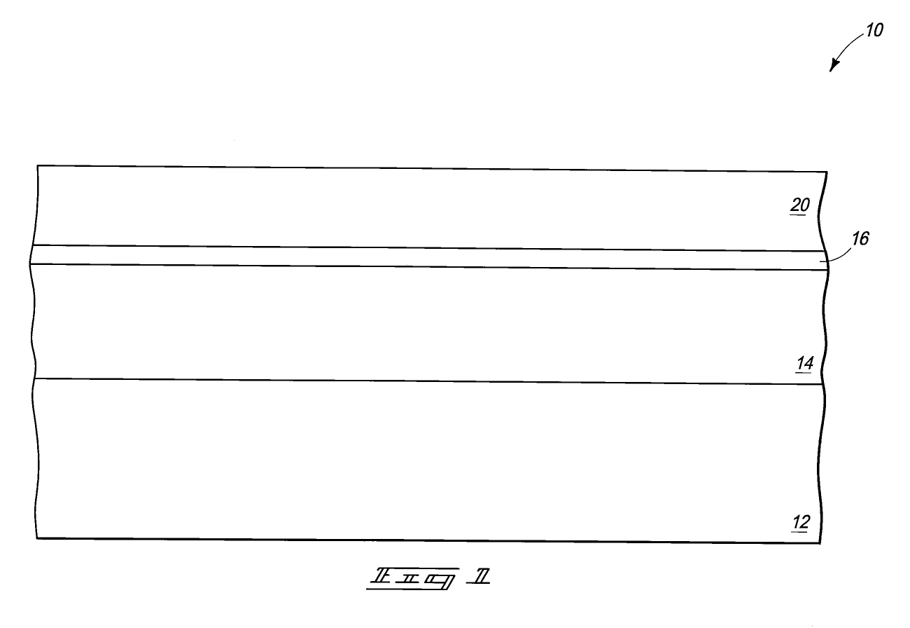

Example embodiments of methods for trimming photoresist and utilizing the trimmed photoresist are described with reference to FIGS. 1-10.

Referring to FIG. 1, such shows a construction 10 that comprises a base 12, a material 14 over the base, a hardmask 16 over the material 14, and photoresist 20 over the hardmask.

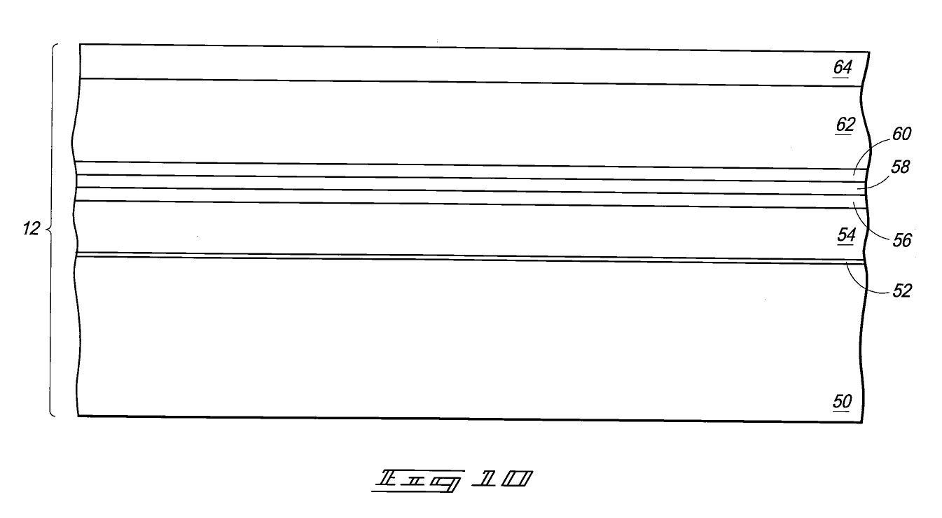

Base 12 comprises one or more materials which ultimately are to be patterned. The base is shown to be homogeneous in FIG. 1 in order to simplify the drawing. In some embodiments, the base may be homogeneous, as shown in FIGS. 1-9. In other embodiments, the base may be heterogeneous, with an example of such other embodiments being shown and described with reference to FIG. 10. In some embodiments, the base may comprise semiconductor material (for instance, monocrystalline silicon of a silicon wafer), supporting one or more layers that are ultimately to be patterned into structures utilized in integrated circuitry. The various layers may comprise any suitable materials, such as, for example, one or more of various semiconductive materials, insulative materials, and conductive materials.

If base 12 comprises semiconductor material, the base may be referred to as a semiconductor substrate or semiconductor construction; with the terms “semiconductor substrate” and “semiconductor construction” meaning any construction comprising semiconductive material, including, but not limited to, bulk semiconductive materials such as a semiconductive wafer (either alone or in assemblies comprising other materials thereon), and semiconductive material layers (either alone or in assemblies comprising other materials). The term “substrate” means any supporting structure, including, but not limited to, the semiconductor substrates described above.

Material 14 comprises a composition suitable for being selectively patterned with various spacers (described below), and suitable for being used to pattern one or more materials of the underlying base 12 (i.e., comprises a composition to which one or more materials of the underlying base may be selectively etched). In some embodiments, material 14 comprises, consists essentially of, or consists of carbon. Example carbon-containing materials are amorphous carbon, transparent carbon, and carbon-containing polymers. Example carbon-containing polymers include spin-on-carbons (SOCs). An example thickness range for material 14 is from about 700 Angstroms to about 2,000 Angstroms.

Hardmask 16 may be homogeneous or heterogeneous. In some embodiments, hardmask 16 may correspond to a deposited antireflective coating (DARC), and may comprise, consist essentially of, or consist of silicon oxynitride. An example thickness range for hardmask 16 is from about 200 Angstroms to about 400 Angstroms. The hardmask 16 provides an etch stop between the patterned mask 20 and the material 14. Such may be desired if the patterned mask 20 comprises a composition that is difficult to selectively remove relative to the material 14 (for instance, if the patterned mask 20 and the material 14 both comprise organic materials). The term “selective removal” means that one material is removed faster than another, which includes, but is not limited to, processes that are 100% selective for one material relative to another. In embodiments in which the patterned mask 20 comprises a composition that can be selectively removed relative to material 14, the hardmask 16 may be omitted.

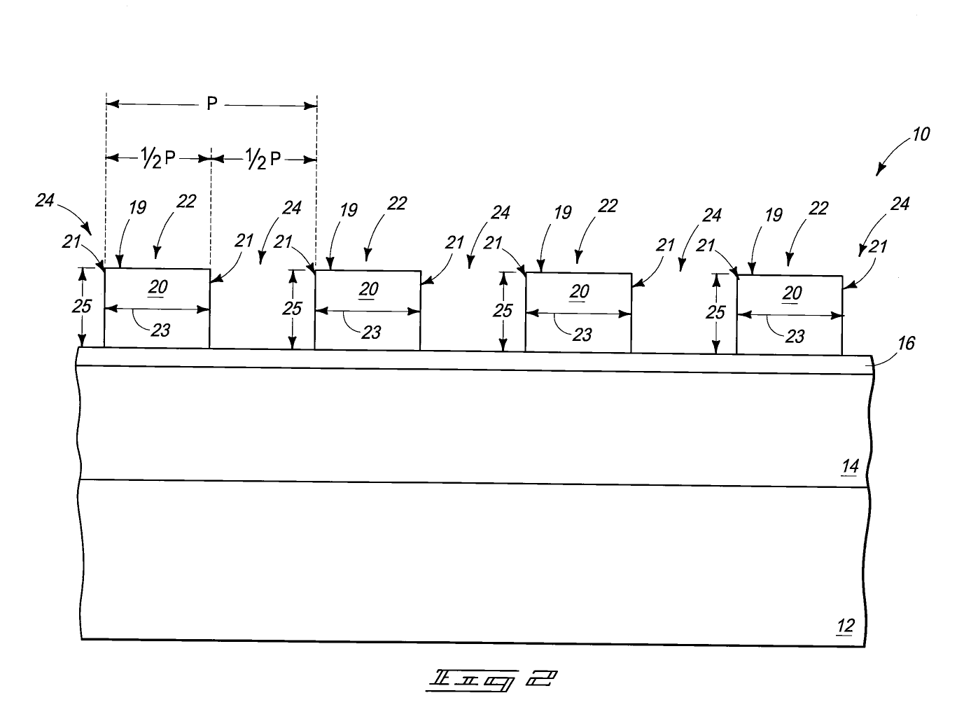

Referring to FIG. 2, photoresist 20 is patterned into a plurality of spaced-apart features 22, which alternate with gaps 24 between the features. In some embodiments, the features may correspond to lines extending in and out of the page relative to the shown cross-section section of FIG. 2. Photoresist 20 may be formed into the shown pattern with photolithographic processing (i.e., by exposing the photoresist to patterned actinic radiation, followed by utilization of developer to selectively remove some regions of the photoresist).

In the shown embodiment, the features 22 and gaps 24 are formed to a pitch, P, with individual features having widths ½ P and with individual gaps having widths ½ P. In some embodiments, the widths ½ P may correspond to minimum photolithographic feature dimensions that may be formed with the photolithographic processing utilized to create patterned mask 20, and thus the pitch P may correspond to a minimum pitch that can be created with such photolithographic processing.

Although the gaps and features are shown having the same widths as one another, in other embodiments at least some of the gaps may have widths different than at least some of the features. Also, in some embodiments one or more of the features may be formed to a different width than one or more of the other features; and/or one or more of the gaps may be formed to a different width than one or more of the other gaps.

Each of the features 22 has a top surface 19, sidewall surfaces 21, a width 23 between the sidewall surfaces, and a height 25 from a bottom of the feature to the top surface of the feature.

In some embodiments, the shown region of construction 10 may correspond to a location where part of a memory array is to be formed, and the mask 20, together with subsequent processing described below, may be utilized to define a repeating pattern of structures that are ultimately to be formed across the memory array region.

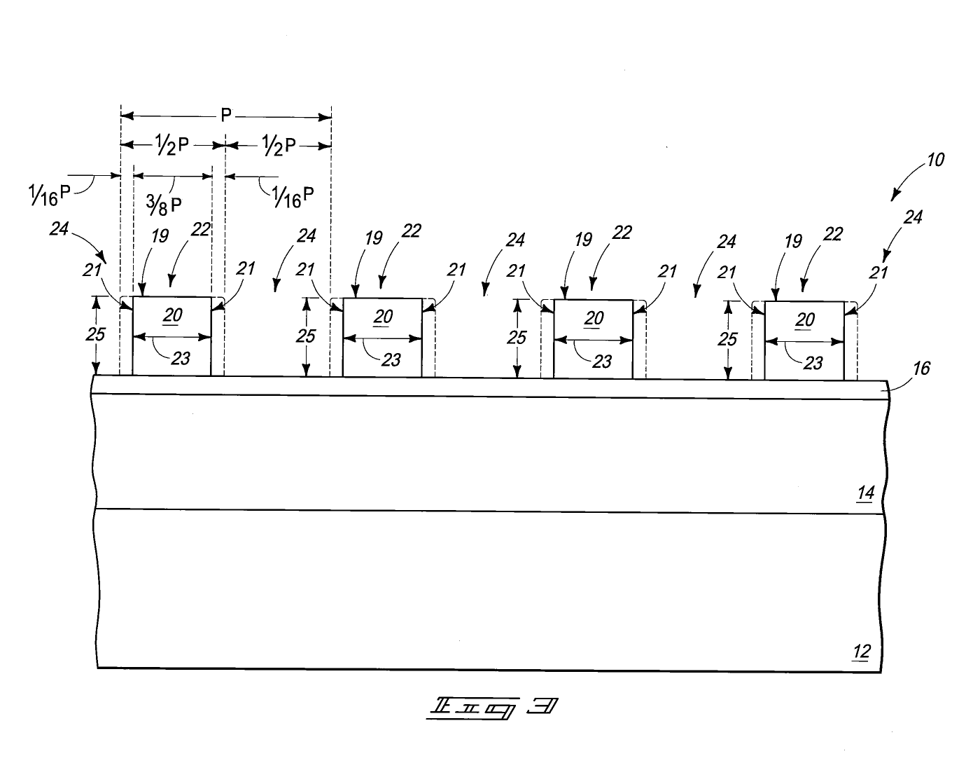

Referring to FIG. 3, an etch is conducted to laterally trim features 22. In the illustrated embodiment, the etch has advantageously reduced the widths 23 of the features, without any substantial reduction of the heights 25 of the features. The lateral trimming of features 22 moves sidewalls 21 inwardly. The original locations of sidewalls 21 (i.e., the locations of the sidewalls at the processing stage of FIG. 2) is shown in FIG. 3 in dashed-line view to assist the reader in understanding the dimensional changes that occurred to the features 22 through the lateral trimming. In the illustrated embodiment, the lateral trimming reduces the widths of features 22 from a dimension of about ½ P to a dimension of about ⅜ P; and thus corresponds to removal of about 1/16 P from each of the sides of the individual features 22. Such dimensional changes may be appropriate in pitch-doubling applications. In other embodiments, the amount of lateral trimming may be varied relative to the shown amount to render the trimmed features suitable for other desired purposes.

For purposes of interpreting this document and the claims that follow, a “substantial reduction” of a dimension is a reduction of greater than or equal to 5 percent. Accordingly, the heights of the features 22 are not “substantially reduced” (and are instead “substantially maintained”) if the heights remaining after the trim are not reduced by more than about five percent relative to the original heights. In some embodiments, the lateral trimming may reduce the widths of features 22 without having any negative impact on the heights of such features; and accordingly the heights of the features after the lateral trimming will be identical to the heights of the features before the lateral trimming, or may be even taller than the heights of the features before the lateral trimming.

The lateral trimming of features 22 utilizes an etchant containing chloroform (CHCl₃) and an oxidant (for instance, O₂). The etchant may also include another carbon-containing material besides chloroform. In some embodiments, such other carbon-containing material may be selected from the group consisting of CO, CO₂, CHF₃, CH₄, CF₄, CH₂F₂, and mixtures thereof. In an example embodiment, the etchant may comprise chloroform, O₂, and carbon dioxide, with such components being provided in a ratio of about 7:5:30. In some embodiments the additional carbon-containing material besides chloroform may be an oxidant, and in other embodiments such additional carbon-containing material may not be an oxidant.

The amount of lateral etching may be modified by modifying the time of exposure to the etchant. Since the lateral etching of photoresist features may occur without substantially impacting the heights of the photoresist features, a large amount of lateral etching may be conducted in some embodiments without compromising the suitability of the photoresist features for subsequent process steps.

The above-described etchant may be utilized in a reaction chamber, and may be utilized under any suitable process conditions. Example process conditions may include a pressure within the chamber of from about 3 millitorr to about 20 millitorr (for instance, about 10 millitorr); a non-biased power of from about 250 watts to about 1000 watts (for instance, about 350 watts); and a temperature of from 0° C. to 70° C. (for instance, a temperature of from about 30° C. to about 40° C.). The flow rates of chloroform, O₂ and CO₂ through the chamber may be about 21 standard cubic centimeters per minute (sccm), 15 sccm and 90 sccm, respectively. This ratio, especially CHCl₃:O₂, may be adjusted to tailor etch rate. Additionally, helium carrier gas may be flowed into the chamber at a rate of 60 sccm. The treatment time may be any time suitable to accomplish a desired amount of etching, and in some embodiments may be a time of greater than or equal to about 45 seconds.

In addition to the advantage of accomplishing a lateral etch of a photoresist feature without substantially impacting the height of the feature, the etching conditions discussed herein may also advantageously enable the straight, vertical profiles of the sidewall edges 21 to be maintained during the lateral etching, as shown in FIG. 3. A problem of some prior art photoresist trimming methods is that the methods alter the profile of sidewall edges of the photoresist features during the photoresist trimming. Such alteration may lead to anomalous structures being present at the bottoms of the sidewalls after the lateral trimming, with such anomalous structures being known in the art as “feet”. The problem of formation of such anomalous structures is thus often referred to in the art as a “foot problem”.

A possible mechanism by which the etchants described herein may function to enable lateral etching of photoresist features while avoiding the prior art “foot problem” and/or undesired reduction in height of the photoresist features is that the Cl components and CH components are balanced to enable etching to occur from vertical surfaces of photoresist features much more rapidly than it occurs from horizontal surfaces of the features. More specifically, the Cl components and CH components are balanced such that a rate of polymer deposition matches the rate of etching from horizontal surfaces of photoresist features (for instance, the top surfaces 19 shown in FIG. 2); and yet such that a rate of etching from the vertical surfaces (for instance, the sidewall surfaces 21 shown in FIG. 2) exceeds the rate of polymer deposition on such vertical surfaces. This mechanism is provided to assist the reader in understanding the invention, and is not to limit the invention except to the extent, if any, that such mechanism is expressly recited in the claims.

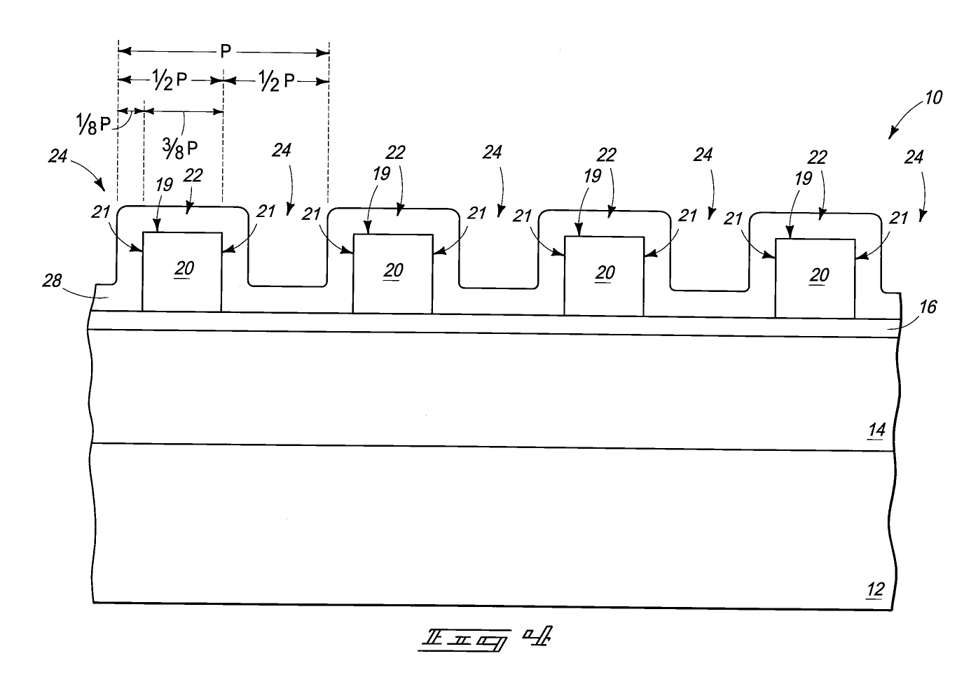

The trimmed photoresist features 22 may be utilized for patterning underlying materials. For instance, the trimmed photoresist features may be used as a mask during an etch into the underlying materials and/or during an implant of dopant into the underlying materials. Alternatively, or additionally, the trimmed photoresist features may be used as a template in a pitch-multiplication process; and specifically may be used for patterning another set of features that will ultimately be utilized as a mask. FIGS. 4-9 illustrate example process stages of an embodiment in which the trimmed photoresist features are utilized as a template in a pitch-multiplication process.

Referring to FIG. 4, spacer material 28 is formed over and between the trimmed photoresist features 22. The spacer material may comprise any suitable material, and may be formed with any suitable processing. For instance, the spacer material may comprise, consist essentially of, or consist of one or more of silicon dioxide, silicon nitride and silicon oxynitride; and may be formed by one or both of chemical vapor deposition (CVD) and atomic layer deposition (ALD).

The spacer material 28 is shown formed to a thickness of about ⅛ P, which can be appropriate for a pitch-doubling process. In other embodiments, the spacer material may be formed to a different thickness relative to the initial pitch, P, of the photolithographic process utilized to pattern the photoresist.

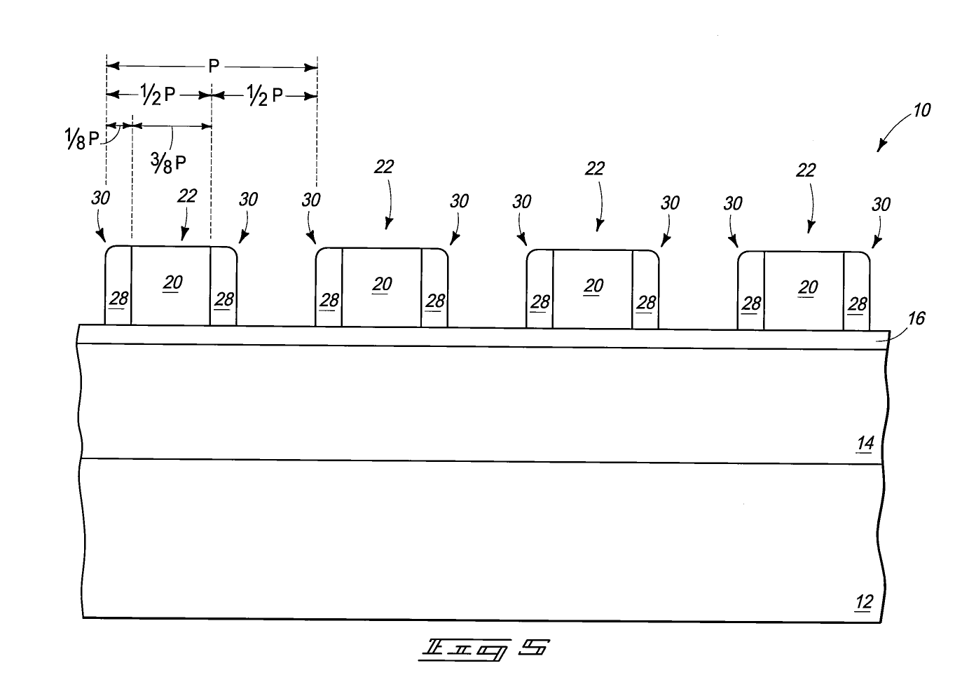

Referring to FIG. 5, an anisotropic etch is utilized to pattern spacer material 28 into a plurality of spacers 30 along the sidewalls 21 of the trimmed photoresist features 22. The spacers are the same height as the trimmed photoresist features. Accordingly, the utilization of a trim process that maintains the height of the photoresist features advantageously enables spacers 30 to be formed to the original height 25 (FIG. 2) of the photolithographically-patterned features 22.

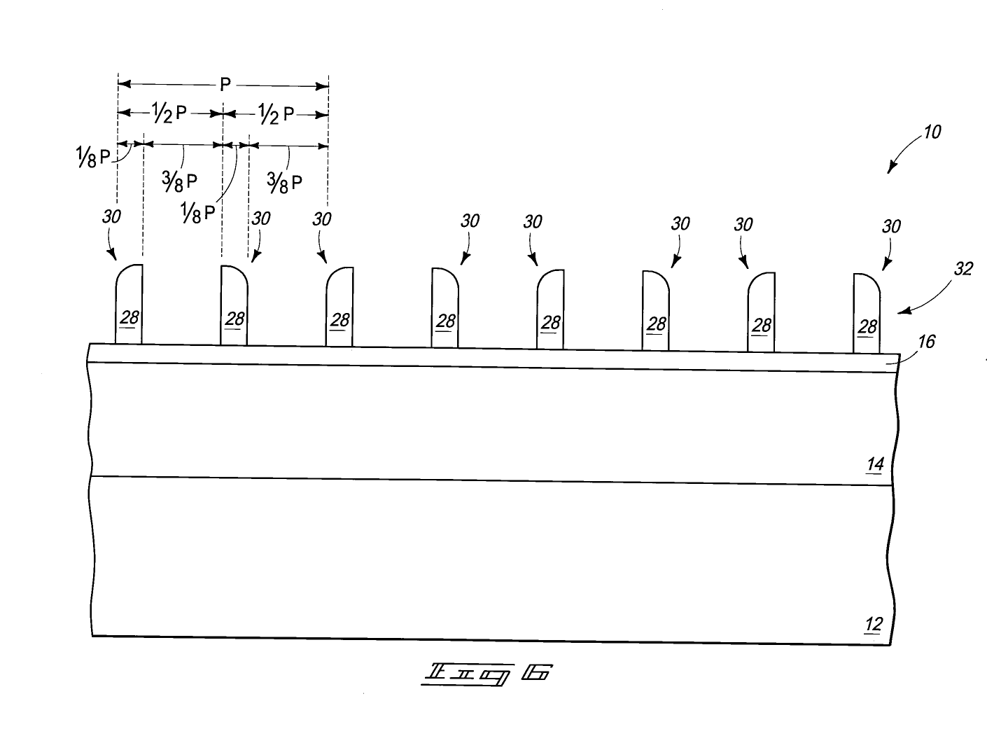

Referring to FIG. 6, photoresist features 22 (FIG. 5) are removed to leave a patterned mask 32 corresponding to the spacers 30. The mask 32 has a pitch of ½ P. Thus, the pitch of mask 32 is reduced by a factor of two relative to the original pitch, P, of the photolithographically-patterned photoresist (which is referred to in the art as a pitch-doubling process).

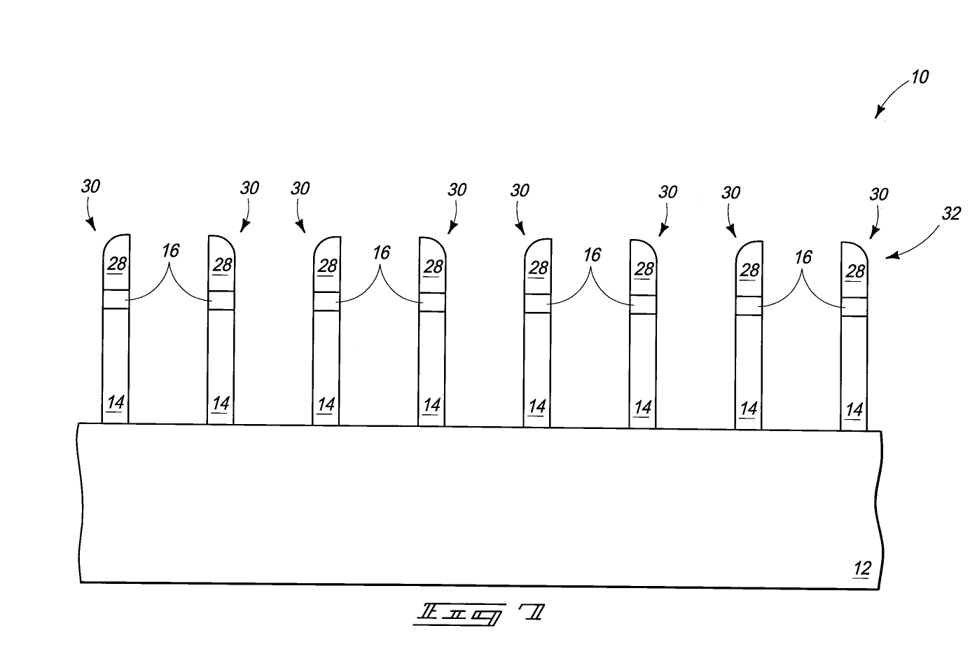

Referring to FIG. 7, materials 14 and 16 are etched selectively relative to spacer material 28 to thereby transfer a pattern from mask 32 into the materials 14 and 16. A problem that can occur during the etching of materials 14 and 16 is that the etching conditions may also remove some of the material 28 (as shown). In other words, the etch conditions utilized to remove materials 14 and 16 may not be 100 percent selective for materials 14 and 16 relative to spacer material 28. It is desired that spacers 30 have sufficient starting height so that the spacers remain as a viable mask during the etching into underlying materials even as some of the spacer material is lost during such etching. An advantage of the photoresist trim chemistry described herein (and specifically described above with reference to FIG. 3) is that such may substantially maintain the initial height of the photoresist, and thus may enable the spacers 30 to be formed to a height comparable to the initial height of the photoresist. In contrast, prior art processes that reduce the height of the photoresist during the lateral trimming of the photoresist will lead to formation of spacers that are shorter than those formed by the methodology described herein. Accordingly, prior art processes for trimming photoresist may lead to fabrication of spacers which are too short to be utilized for subsequent processing, whereas the photoresist trimming methodologies described herein may be utilized to fabricate spacers having appropriate height to be suitable for such subsequent processing.

In the discussion of FIG. 3 it was mentioned that the photoresist features 22 could be utilized directly as a mask for patterning underlying materials. If the photoresist features are utilized directly as a mask, similar problems to those discussed above with reference to FIG. 7 may still result in that the patterning of the underlying materials may utilize etch chemistry that is not 100 percent selective relative to the photoresist features 22. Accordingly, the photoresist features may be eroded during the etching of the underlying materials, and it is therefore desirable to form the photoresist features 22 to a height such that the features will remain as a viable mask in spite of the erosion of such features during the etching.

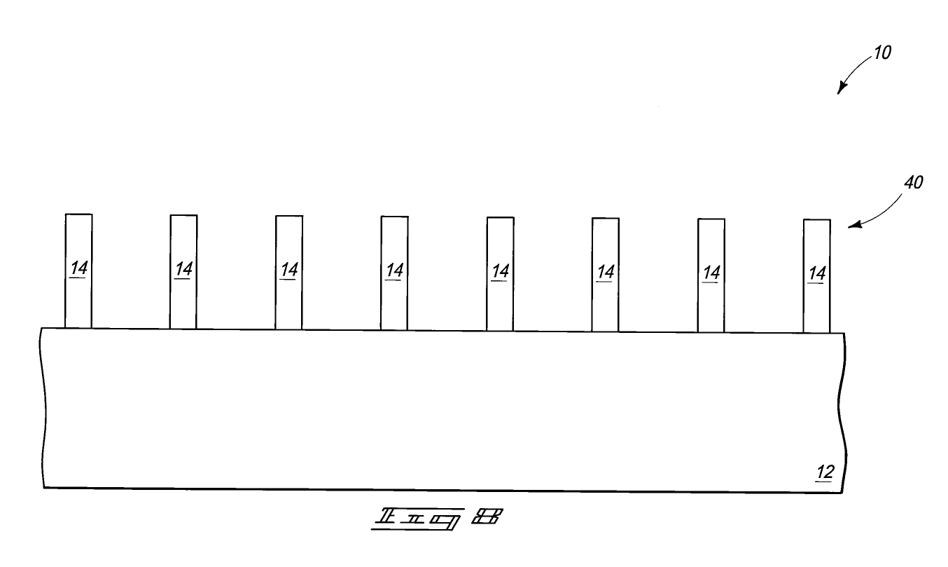

Referring to FIG. 8, spacer material 28 and hardmask material 16 (FIG. 7) are removed to leave a patterned mask 40 corresponding to the features formed in the material 14.

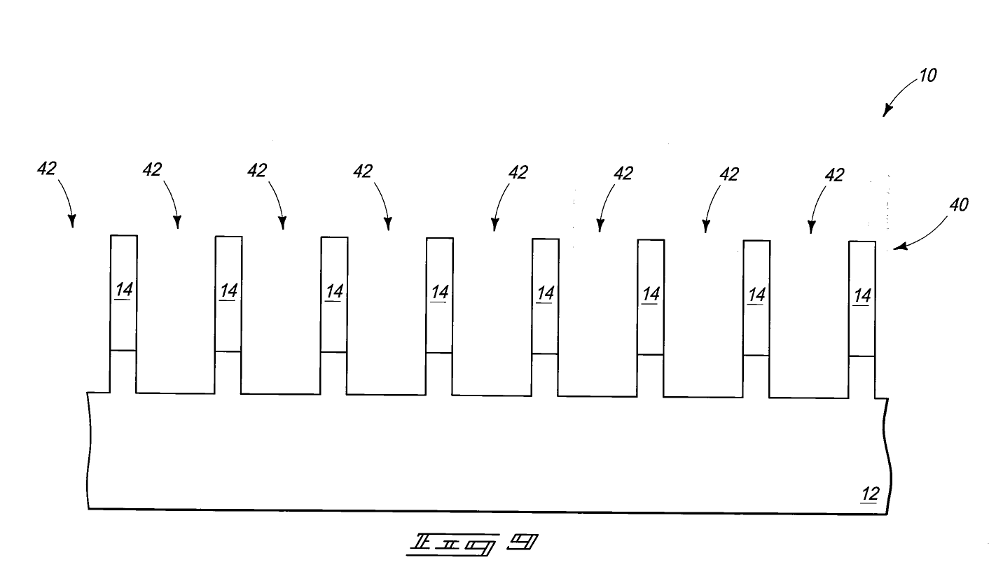

Referring to FIG. 9, the patterned mask 40 is utilized during etching of one or more materials of base 12, and thus openings 42 are shown extended into base 12. The etching of one or more materials of the base is one of several methods in which a pattern from mask 40 may be used to impart a pattern into one or more materials of base 12. Another example method comprises utilization of mask 40 to pattern a dopant implant.

Although spacer material 28 and hardmask material 16 (FIG. 7) are shown being removed prior to utilizing patterned mask 40 for imparting a pattern into base 12, in other embodiments one or both of the spacer material 28 and hardmask material 16 (FIG. 7) may remain at a processing stage analogous to that of FIG. 9 in which the patterned mask 40 is utilized for imparting a pattern into base 12.

The processing of FIGS. 1-9 may be utilized for patterning numerous devices, such as, for example, gates or other components utilized for nonvolatile memory devices (for instance, gates of NAND devices); and/or for patterning gates or other components of volatile memory devices. The base 12 may be configured to comprise appropriate materials so that such materials may be patterned into the desired circuitry. For instance, FIG. 10 shows an example embodiment of base 12 configured for fabrication of nonvolatile memory devices.

The base 12 of FIG. 10 includes a supporting material 50, and a stack of materials 52, 54, 56, 58, 60, 62 and 64 over the supporting material. The supporting material may, for example, comprise, consist essentially of, or consist of appropriately-doped monocrystalline silicon. Material 52 may correspond to tunnel dielectric; and may, for example, comprise, consist essentially of, or consist of silicon dioxide. Material 54 may be floating gate material or charge-trapping material; and in some embodiments may comprise polycrystalline silicon. Materials 56, 58 and 60 may be dielectric materials, and in some embodiments may comprise one or more of silicon dioxide, hafnium oxide, aluminum oxide, and zirconium oxide. Material 62 may be a control gate material, and in some embodiments may comprise one or more of metal, metal-containing composition and conductively-doped semiconductor material. Material 64 may be an electrically insulative capping material, and in some embodiments may comprise one or more of silicon dioxide, silicon nitride and silicon oxynitride.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

I/we claim:

1. A method for trimming a photoresist feature comprising exposing said photoresist feature to a mixture containing chloroform and an oxidant.

2. The method of claim 1 wherein the oxidant is O₂.

3. The method of claim 1 wherein the mixture comprises an additional carbon-containing material besides the chloroform.

4. The method of claim 3 wherein the additional carbon-containing material is an oxidant.

5. The method of claim 3 wherein said additional carbon-containing material is selected from the group consisting of CF₄, CH₂F₂, CHF₃, CH₄ and CO₂.

6. The method of claim 5 wherein said additional carbon-containing material contains CH, and wherein CH-containing components are balanced relative to Cl-containing components in the mixture to etch more rapidly from a vertical surface of the photoresist feature than from a horizontal surface of the photoresist feature.

7. The method of claim 5 wherein said additional carbon-containing material contains CH, and wherein CH-containing components are balanced relative to Cl-containing components in the mixture to so that a rate of etching from a horizontal surface of the photoresist feature is about matched to a rate of polymer deposition on the horizontal surface, and so that a rate of etching from a vertical surface of the photoresist feature is faster than a rate of polymer deposition on the vertical surface.

8. The method of claim 3 wherein said additional carbon-containing material is CO₂.

9. A method of forming a pattern, comprising:
photolithographically forming at least one photoresist feature over a base, the photoresist feature having a height and a width; and
exposing the photoresist feature to a combination of chloroform, oxidant and additional carbon-containing material besides chloroform to reduce the width of the photoresist feature while substantially maintaining the height of the photoresist feature.

10. The method of claim 9 wherein the base comprises a semiconductor substrate.

11. The method of claim 9 wherein the base comprises a carbon-containing material over a semiconductor substrate.

12. The method of claim 11 wherein the base comprises a hardmask over the carbon-containing material.

13. The method of claim 12 wherein the hardmask comprises silicon oxynitride.

14. The method of claim 12 wherein the hardmask consists of silicon oxynitride.

15. The method of claim 9 wherein the exposing is conducted in a chamber while a pressure within the chamber is from about 3 millitorr to about 20 millitorr.

16. The method of claim 9 wherein the oxidant is O₂.

17. The method of claim 16 wherein the additional carbon-containing material is CO₂.

18. The method of claim 17 wherein the exposing is conducted in a chamber while maintaining relative flow rates of the chloroform:O₂:CO₂ of about 7:5:30.

19. A method of forming a pattern, comprising:
photolithographically forming a plurality of photoresist features over a base, the individual photoresist features having heights and widths;
exposing the photoresist features to a combination of chloroform, oxidant and additional carbon-containing material besides chloroform to reduce the widths of the photoresist features while substantially maintaining the heights of the photoresist features;
after reducing the widths of the photoresist features, forming spacer material between and over the photoresist features;
anisotropically etching the spacer material to form spacers along sidewalls of the photoresist features; and
removing the photoresist features to leave the spacers as the pattern over the base.

20. The method of claim 19 wherein the exposing is conducted in a chamber while a pressure within the chamber is from about 3 millitorr to about 20 millitorr.

21. The method of claim 19 wherein the oxidant is O₂.

22. The method of claim 19 wherein the additional carbon-containing material is CO₂.

23. The method of claim 19 wherein:
the oxidant is O₂,
the additional carbon-containing material is CO₂, and
the exposing is conducted in a chamber while maintaining relative flow rates of the chloroform:O₂:CO₂ of about 7:5:30.
